(19) United States
(12) Patent Application Publication
(10) Pub. No.: US 2006/0013946 A1
(43) Pub. Date: Jan. 19, 2006

(54) Methods of forming a thin film structure, and a gate structure and a capacitor including the thin film structure

(76) Inventors: Hong-Bae Park, Seoul (KR); Sang-Bom Kang, Seoul (KR); Beom-Jun Jin, Seoul (KR); Yu-Gyun Shin, Gyeonggi-do (KR)

Correspondence Address: D. Scott Moore;Myers Bigel Sibley & Sajovec, Post Office Box 37428, Raleigh, NC, 27627, US

(21) Appl. No.: 11/182,893

(22) Filed: Jul. 15, 2005

(30) Foreign Application Priority Data
Jul. 15, 2004 (KR) 2004-55057

(51) Int. Cl. C23C 16/00; B05D 5/12

(52) U.S. Cl. 427/79; 427/248.1

(57) ABSTRACT

A thin film structure is formed that includes hafnium silicon oxide using an atomic layer deposition process. A first reactant including tetrakis ethyl methyl amino hafnium (TEMAH) is introduced onto a substrate. A first portion of the first reactant is chemisorbed to the substrate, whereas a second portion of the first reactant is physorbed to the first portion of the first reactant. A first oxidant is provided onto the substrate. A first thin film including hafnium oxide is formed on the substrate by chemically reacting the first oxidant with the first portion of the first reactant. A second reactant including amino propyl tri ethoxy silane (APTES) is introduced onto the first thin film. A first portion of the second reactant is chemisorbed to the first thin film, whereas a second portion of the second reactant is physorbed to the first portion of the second reactant. A second oxidant is provided onto the first thin film. A second thin film including silicon oxide is formed on the first thin film by chemically reacting the second oxidant with the first portion of the second reactant.

### CROSS REFERENCE TO RELATED APPLICATION

This application claims the benefit under 35 USC § 119 of Korean Patent Application No. 2004-55057 filed on Jul. 15, 2004 the disclosure of which is hereby incorporated herein by reference in its entirety.

### BACKGROUND OF THE INVENTION

1. Field of the Invention

The present invention relates to methods of forming a thin film structure using an atomic layer deposition (ALD) process, methods of forming a gate structure including the thin film structure, and methods of forming a capacitor including the thin film structure. More particularly, the present invention relates to methods of forming a thin film structure including hafnium silicon oxide using an ALD process, methods of forming a gate structure including the thin film structure, and methods of forming a capacitor including the thin film structure.

2. Description of Related Art

A material having a higher dielectric constant may be widely used for a gate insulation layer of a transistor or a dielectric layer of a capacitor. A higher dielectric constant may have a thin equivalent oxide thickness (ETO) and may more efficiently reduce a leakage current generated between a gate electrode and a channel region or between a lower electrode and an upper electrode.

A hafnium oxide (HfO₂) layer has been recently used for the gate insulation layer or the dielectric layer. For example, a method of forming the hafnium oxide layer is disclosed at U.S. Pat. No. 6,348,346 issued to Gilmer.

Because the hafnium oxide layer may be crystallized at a temperature of above about 300° C., however, a leakage current may rapidly increase in a semiconductor device including the hafnium oxide layer. In particular, when the hafnium oxide layer is used for a gate insulation layer and a gate conductive layer of polysilicon is formed on the hafnium oxide layer, electron mobility in a channel region may be reduced because impurities, such as boron (B), may penetrate into the hafnium oxide layer.

Considering the above-mentioned problem, a hafnium silicon oxide (HfSi_{X}O_{Y}) layer has been developed for various semiconductor devices. The hafnium silicon oxide layer is typically formed using a sputtering process, a chemical vapor deposition (CVD) process, or an ALD process.

When the hafnium silicon oxide layer is manufactured by the sputtering process, the throughput of the manufacturing process may be reduced. When the hafnium silicon oxide layer is formed by the CVD process, concentrations of hafnium and silicon contained in the hafnium silicon oxide layer may be hard to control and the hafnium silicon oxide layer may not have a thickness of below about 50 Å. However, the hafnium silicon oxide layer may have a relatively thin thickness and the concentrations of hafnium and silicon may be easily controlled when the hafnium silicon oxide layer is formed by the ALD process. For example, methods of forming a hafnium silicon oxide layer are disclosed in U.S. patent application Publication No. 2003/232506, Japanese Laid Open Patent Publication No. 2003-347297, Korean Laid Open Patent Publication No. 2002-32054, and Korean Laid Open Patent Publication No. 2001-35736.

In the above U.S. patent application Publication No. 2003/232506, a hafnium silicon oxide layer is formed by using tetrakis diethyl amino hafnium (TDEAH) as a hafnium precursor, and by using tetrakis diethyl amino silicon (TDMAS) as a silicon precursor.

In the above Japanese Laid Open Patent Publication No. 2003-347297, a hafnium silicon oxide layer is formed using TDEAH as a hafnium precursor and using tetra methoxy silane (TMOS) as a silicon precursor. In addition, a concentration ratio between hafnium and silicon included in the hafnium silicon oxide layer is controlled by adjusting amounts of TDEAH and TMOS.

In the above Korean Laid Open Patent Publication No. 2002-32054, a hafnium silicon oxide layer is formed by chemically reacting a hafnium film with a silicon compound such as SiH₄, Si₂H₆, or SiCl₂H₂.

According to the conventional method of forming a hafnium silicon oxide layer, the hafnium silicon oxide layer may not have desired thickness and electrical characteristics because a hafnium precursor may not easily react with a silicon precursor. That is, the silicon precursor may not have good reactivity relative to the hafnium precursor so that the hafnium silicon oxide layer may have an undesired thickness or poor electrical characteristics.

### SUMMARY OF THE INVENTION

According to some embodiments of the present invention, a thin film structure is formed that includes hafnium silicon oxide using an atomic layer deposition process. A first reactant including tetrakis ethyl methyl amino hafnium (TEMAH) is introduced onto a substrate. A first portion of the first reactant is chemisorbed to the substrate, whereas a second portion of the first reactant is physorbed to the first portion of the first reactant. A first oxidant is provided onto the substrate. A first thin film including hafnium oxide is formed on the substrate by chemically reacting the first oxidant with the first portion of the first reactant. A second reactant including amino propyl tri ethoxy silane (APTES) is introduced onto the first thin film. A first portion of the second reactant is chemisorbed to the first thin film, whereas a second portion of the second reactant is physorbed to the first portion of the second reactant. A second oxidant is provided onto the first thin film. A second thin film including silicon oxide is formed on the first thin film by chemically reacting the second oxidant with the first portion of the second reactant.

In other embodiments of the present invention, the first oxidant may include ozone (O₃), water (H₂O) vapor, hydrogen peroxide (H₂O₂), methanol (CH₃OH) or ethanol (C₂H₅OH). These may be used alone or in a mixture thereof. Additionally, the second oxidant may include ozone, water vapor, hydrogen peroxide, methanol, or ethanol. These may be used alone or in a mixture thereof.

In still other embodiments of the present invention, the thin film structure may comprise a gate insulation layer of a transistor or a dielectric layer of a capacitor.

In still other embodiments of the present invention, the thin film structure may be formed at a temperature of about 150 to about 400° C.

In still other embodiments of the present invention, introducing the first reactant, chemisorbing the first portion of the first reactant, physorbing the second portion of the first reactant, providing the first oxidant, and forming the first thin film may be performed at least once.

In still other embodiments of the present invention, introducing the second reactant, chemisorbing the first portion of the second reactant, physorbing the second portion of the second reactant, providing the second oxidant, and forming the second thin film may be performed at least once.

In still other embodiments of the present invention, introducing the first reactant, chemisorbing the first portion of the first reactant, physorbing the second portion of the first reactant, providing the first oxidant, forming the first thin film, introducing the second reactant, chemisorbing the first portion of the second reactant, physorbing the second portion of the second reactant, providing the second oxidant, and forming the second thin film may be performed at least once.

In still other embodiments of the present invention, after the second portion of the first reactant is removed, an unreacted portion of the first oxidant is removed. The second portion of the second reactant is also removed, and then an unreacted portion of the second oxidant is removed.

In further embodiments of the present invention, a gate structure is formed by forming a gate insulation layer including hafnium silicon oxide on a substrate by an atomic layer deposition process using TEMAH, APTES, and oxidants. A gate conductive layer is formed on the gate insulation layer. A gate pattern including a gate insulation layer pattern and a gate conductive layer pattern is formed by partially etching the gate conductive layer and the gate insulation layer.

In other embodiments of the present invention, the gate insulation layer is formed by introducing a first reactant including the TEMAH onto the substrate. A first portion of the first reactant is chemisorbed to the substrate, whereas a second portion of the first reactant is physorbed to the first portion of the first reactant. The second portion of the first reactant is removed. A first oxidant is provided onto the substrate. A first thin film including hafnium oxide is formed on the substrate by chemically reacting the first oxidant with the first portion of the first reactant. An unreacted portion of the first oxidant is removed. A second reactant including the APTES is introduced onto the first thin film. A first portion of the second reactant is chemisorbed to the first thin film, whereas a second portion of the second reactant is physorbed to the first portion of the second reactant. The second portion of the second reactant is removed. A second oxidant is provided onto the first thin film. A second thin film including silicon oxide is formed on the first thin film by chemically reacting the second oxidant with the first portion of the second reactant. An unreacted portion of the second oxidant is removed.

In further embodiments of the present invention, a capacitor is formed by forming a lower electrode on a substrate. A dielectric structure including hafnium silicon oxide is formed on the lower electrode by an atomic layer deposition process using TEMAH, APTES, and oxidants. An upper electrode is formed on the dielectric structure. In forming the dielectric structure, a first reactant including the TEMAH is introduced onto the substrate. A first portion of the first reactant is chemisorbed to the substrate, but a second portion of the first reactant is physorbed to the first portion of the first reactant. The second portion of the first reactant is removed. A first oxidant is provided onto the substrate. A first thin film including hafnium oxide is formed on the substrate by chemically reacting the first oxidant with the first portion of the first reactant. An unreacted portion of the first oxidant is removed. A second reactant including the APTES is introduced onto the first thin film. A first portion of the second reactant is chemisorbed to the first thin film, but a second portion of the second reactant is physorbed to the first portion of the second reactant. The second portion of the second reactant is removed. A second oxidant is provided onto the first thin film. A second thin film including silicon oxide is formed on the first thin film by chemically reacting the second oxidant with the first portion of the second reactant. An unreacted portion of the second oxidant is removed.

According some embodiments of the present invention, a thin film structure including hafnium silicon oxide may be relatively easily formed using TEMAH and APTES both of which have good reactivity with respect to each other. Particularly, the thin film structure may have a desired concentration ratio between hafnium and silicon by controlling the numbers of the cycles of the manufacturing processes in the formation of the thin film structure using an ALD process. Because the thin film structure has a relatively high dielectric constant, a semiconductor device that includes a transistor or a capacitor, for example, may have improved electrical characteristics when the thin film structure is used for a gate insulation layer of the transistor or a dielectric layer of the capacitor.

### BRIEF DESCRIPTION OF THE DRAWINGS

Other features of the present invention will be more readily understood from the following detailed description of specific embodiments thereof when read in conjunction with the accompanying drawings, in which:

FIGS. 1 to 8 are cross-sectional views illustrating methods of forming a thin film structure using an atomic layer deposition process in accordance with some embodiments of the present invention;

FIGS. 9 and 10 are cross-sectional views illustrating methods of forming a gate structure in accordance with some embodiments of the present invention;

FIG. 11 is a cross-sectional view illustrating methods of forming a capacitor in accordance with some embodiments of the present invention;

FIG. 12 is a graph illustrating a thickness variation of a thin film structure including hafnium silicon oxide relative to cycles of processes in accordance with some embodiments of the present invention;

FIG. 13 is a graph illustrating impurity concentrations contained in a thin film structure including hafnium silicon oxide in accordance with some embodiments of the present invention;

FIG. 14 is a graph showing crystalline structures of conventional thin films of hafnium oxide and thin film structures including hafnium silicon oxide in accordance with some embodiments of the present invention; and

FIG. 15 is a graph illustrating thickness of thin film structures including hafnium silicon oxide in accordance with some embodiments of the present invention.

### DETAILED DESCRIPTION OF EMBODIMENTS OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the figures. It will be understood that relative terms are intended to encompass different orientations of the device in addition to the orientation depicted in the figures. For example, if the device in one of the figures were turned over, elements described as being on the “lower” side of other elements would then be oriented on “upper” sides of the other elements. The exemplary term “lower,” can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein, but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Methods of Forming a Thin Film Structure

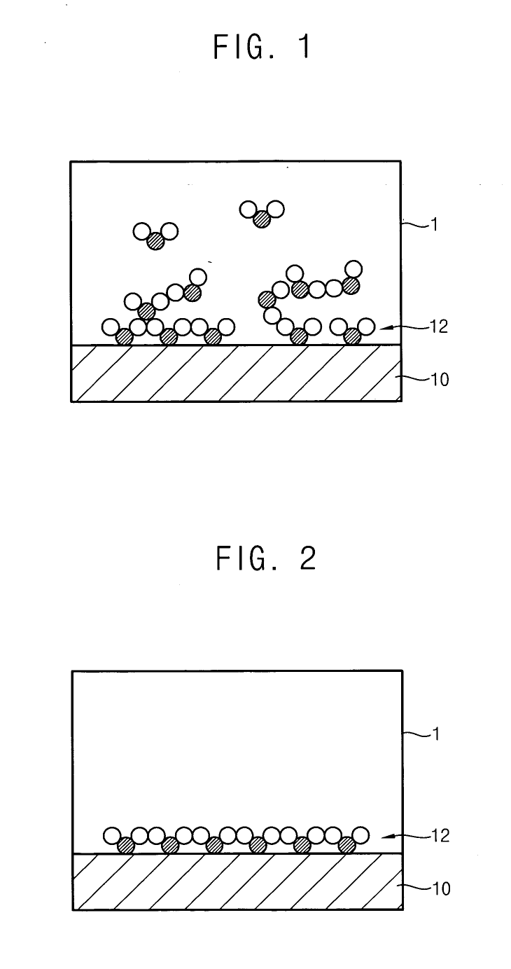

FIGS. 1 to 8 are cross-sectional views illustrating methods of forming a thin film structure using an atomic layer deposition (ALD) process in accordance with some embodiments of the present invention.

Referring to FIG. 1, a substrate 10, such as a silicon wafer, is placed in a chamber 1 in which a temperature of from about 150 to about 400° C. is maintained. Although discussed herein as a silicon wafer, the substrate 10 may include any suitable material.

When the chamber 1 has a temperature of below about 150° C., a first reactant introduced into the chamber 1 may not be suitably reactive. When the chamber 1 has a temperature of above approximately 400° C., ingredients in a first thin film 14 (see FIG. 4) formed on the substrate 10 may be crystallized. The first thin film 14 may be advantageously formed on the substrate 10 using an ALD process when the chamber 1 has a temperature of about 150 to about 450° C. to suppress the first thin film 14 from forming during, for example, a chemical vapor deposition (CVD) process. Although the ALD and the CVD processes are discussed herein, it will be understood that any suitable process may be used in accordance with various embodiments of the present invention. The chamber 1 may have a temperature of about 250 to about 350° C. to form the first thin film 14, which may have improved characteristics. The chamber 1 may have a temperature of about 300° C., and the first thin film 14 may be advantageously formed on the substrate 10 using the ALD process.

After the temperature of the chamber 1 is adjusted, the first reactant is introduced onto the substrate 10 disposed in the chamber 1. The first reactant may be a hafnium precursor including tetrakis ethyl methyl amino hafnium (Hf[NC₂H₅CH₃]₄; TEMAH) in accordance with various embodiments of the present invention. The first reactant may be provided onto the substrate 10 for about 0.5 to about 3 seconds, inclusive. In particular embodiments, the first reactant may be provided onto the substrate 10 for about 1 second.

When the first reactant is provided onto the substrate 10, a first portion 12 of the first reactant is chemisorbed (i.e., chemically absorbed) to the substrate 10. A second portion of the first reactant is physorbed (i.e., physically absorbed) to the chemisorbed first portion 12 and/or the second portion of the first reactant drifts in the chamber 1.

Referring to FIG. 2, a first purge gas is introduced into the chamber 1 after providing the first reactant onto the substrate 10. The first purge gas may include, for example, an inert or inactive gas such as an argon (Ar) gas and/or a nitrogen (N₂) gas. In some embodiments, the first purge gas may include the argon gas only. The first purge gas may be provided onto the substrate 10 for about 0.5 seconds to about 3 seconds, inclusive. In particular embodiments, the first purge gas may be provided onto the substrate 10 for about 1 second.

When the first purge gas is introduced into the chamber 1, the second portion of the first reactant is removed from the chamber 1. That is, the drifting second portion and the physorbed second portion of the first reactant are removed from the substrate 10 and the chamber 1. In particular, radicals of CH contained in TEMAH are removed from the substrate 10 by the first purge gas, whereas hafnium (Hf) and nitrogen (N) may not be removed from the substrate 10 when the first purge gas in provided onto the substrate 10. Thus, the chemisorbed first portion 12 of the first reactant remains on the substrate 10 only.

In some embodiments of the present invention, the radicals of CH may be removed from the substrate 10 and the chamber 1 by vacuumizing the chamber 1 for about 2 to about 3 seconds, inclusive.

In other embodiments of the present invention, the radicals of CH may be removed from the substrate 10 and the chamber 1 by introducing the first purge gas into the chamber 1 and vacuumizing the chamber 1 simultaneously.

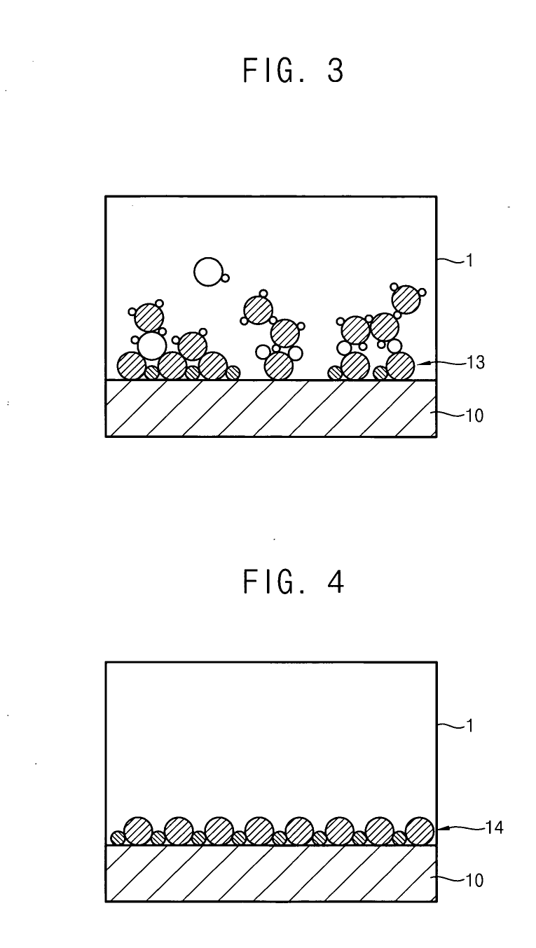

Referring to FIG. 3, a first oxidant is introduced onto the substrate 10 after removing the second portion of the first reactant. The first oxidant may include, for example, ozone (O₃), water (H₂O) vapor, hydrogen peroxide (H2O2), methanol (CH₃OH) or ethanol (C₂H₅OH). These may be used alone or in a mixture thereof. In particular embodiments, the first oxidant may include ozone. The first oxidant may be introduced into the chamber 1 for about 1 second to about 5 seconds, inclusive. In particular embodiments, the first oxidant is provided onto the substrate 10 for about 3 seconds.

When the first oxidant is provided on the substrate 10, the chemisorbed first portion of the first reactant is chemically reacted with the first oxidant so that the chemisorbed first portion of the first reactant is oxidized. Particularly, hafnium (Hf) and nitrogen (N) contained in the TEMAH are oxidized by the first oxidant. The first portion of the first reactant including TEMAH may be easily oxidized because TEMAH has a hydrophile property. As a result, a first metal oxide film 13 is formed on the substrate 10. Here, the first metal oxide film 13 may include N because TEMAH contains N.

Referring to FIG. 4, a second purge gas is introduced into the chamber 1 after forming the first metal oxide film 13. The second purge gas may be the same, or substantially the same, as the first purge gas in accordance with some embodiments of the present invention. For example, the second purge gas may include an argon gas only. The second purge gas may be provided onto the first metal oxide film 13 for the same, or substantially the same, time as that of the first purge gas. For example, the second purge gas may be introduced into the chamber 1 for about 1 to about 5 seconds. In particular embodiments, the second purge gas may be provided onto the first metal oxide film 13 for about 3 seconds.

When the second purge gas is provided into the chamber 1, a remaining portion of the first oxidant (i.e., an unreacted portion of the first oxidant) is removed from the chamber 1. Therefore, the first thin film 14 is formed on the substrate 10. The first thin film 14 may include hafnium oxide.

In some embodiments of the present invention, introducing the first reactant, introducing the first purge gas, providing the fist oxidant, and introducing the second purge gas may be repeatedly performed, thereby forming the first thin film 14 having a desired thickness on the substrate 10.

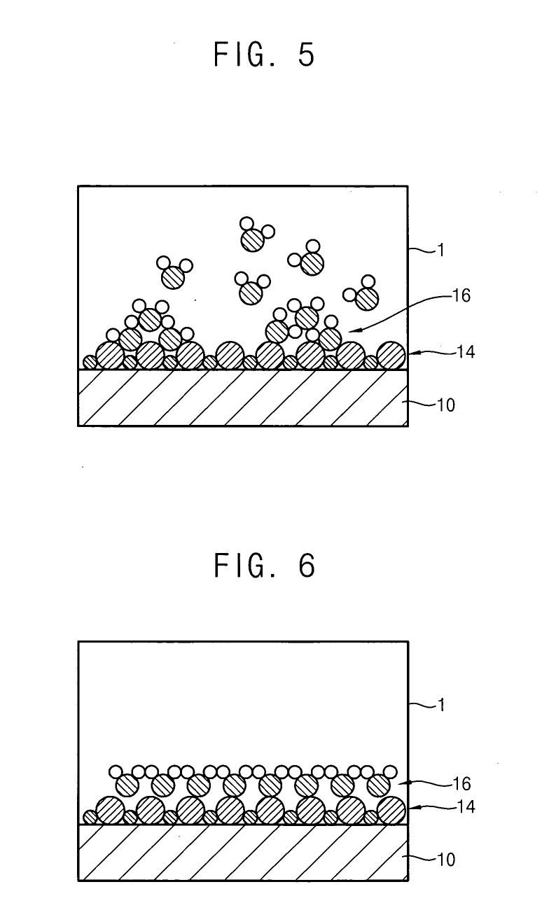

Referring to FIG. 5, a second reactant is provided onto the first thin film 14 formed on the substrate 10. The chamber 1 may have the same, or substantially the same, temperature as described with reference to FIG. 1. The second reactant may include, for example, a silicon (Si) precursor, such as amino propyl tri ethoxy silane (H₂N(CH₂)₃Si(OC₂H₅)₃; APTES). The second reactant may be provided onto the first thin film 14 for about 0.5 to about 3 seconds, inclusive. In particular embodiments, the second reactant may be introduced into the chamber 1 for about 1 second.

When the second reactant is provided onto the first thin film 14, a first portion 16 of the second reactant is chemisorbed to the first thin film 14, and a second portion of the second reactant is partially physorbed to the first portion 16 of the second reactant. Meanwhile, the second portion of the second reactant drifts in the chamber 1.

Referring to FIG. 6, a third purge gas is introduced into the chamber 1 to remove the drifting second portion of the second reactant and the physorbed second portion of the second reactant. Hence, the chemisorbed first portion 16 of the second reactant remains on the first thin film 14. The third purge gas may be the same, or substantially the same, as the first purge gas. For example, the third purge gas may include argon gas only. The third purge gas may be provided onto the first thin film 14 for about 0.5 to about 3 seconds. In particular embodiments, the third purge gas may be provided onto the first thin film 14 for about 1 second.

When the third purge gas is provided onto the first thin film 14, radicals of CH contained in APTES may be removed from the first thin film 14 by the third purge gas. However, silicon included in APTES may not be removed from the first thin film 14 by the third purge gas.

In some embodiments of the present invention, the radicals of CH may be removed from the first thin film 14 and the chamber 1 by vacuumizing the chamber 1 for about 2 to about 3 seconds.

In other embodiments of the present invention, the radicals of CH may be removed from the first thin film 14 and the chamber 1 by introducing the third purge gas into the chamber 1 and vacuumizing the chamber 1 simultaneously.

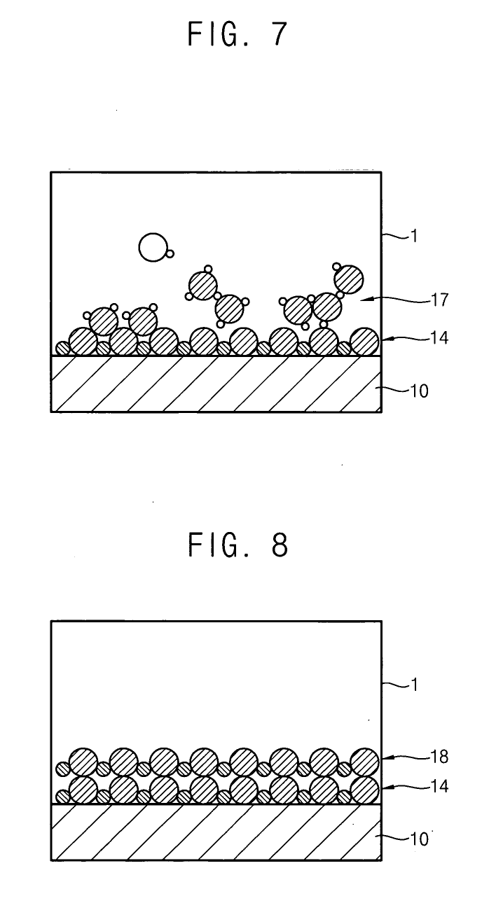

Referring to FIG. 7, a second oxidant is provided onto the chemisorbed first portion 16 of the second reactant formed the first thin film 14. The second oxidant may be introduced into the chamber 1 for about 1 to about 5 seconds. The second oxidant may include, for example, the same, or substantially the same as the first oxidant. In particular embodiments, the second oxidant including ozone may be provided onto the first thin film 14 for about 3 seconds.

When the second oxidant is provided onto the chemisorbed first portion 16 of the second reactant, the second oxidant is chemically reacted with the chemisorbed first portion 16 of the second reactant so that the second oxidant oxidizes the chemisorbed first portion 16 of the second reactant. Particularly, silicon contained in APTES may be easily oxidized because APTES has a hydrophile property. Therefore, a second metal oxide film 17 including silicon oxide is formed on the first thin film 14. When the second reactant includes APTES, the second metal oxide film 17 may include nitrogen.

Referring to FIG. 8, a fourth purge gas is introduced into the chamber 1 for about 1 to about 5 seconds to remove a remaining portion of the second oxidant, which may not chemically react with the chemisorbed first portion 16 of the second reactant. The fourth purge gas may include, for example, an inert or inactive gas such as an argon gas or a nitrogen gas. When the unreacted second oxidant is removed from the chamber 1, a second thin film 18 is formed on the first thin film 14. As a result, a thin film structure including the first and the second thin films 14 and 18 is completed on the substrate 10.

The second thin film 18 may include, for example, silicon oxide. Although the second thin film 18 has been described herein as silicon oxide, it will be understood that any suitable metal oxide material may be used.

In some embodiments of the present invention, introducing the second reactant, introducing the third purge gas, providing the second oxidant, and introducing the fourth purge gas may be repeatedly performed, thereby forming the second thin film 18 having a desired thickness on the first thin film 14.

In some embodiments of the present invention, the thin film structure including hafnium silicon oxide may be easily formed on the substrate 10 because TEMAH has a good reactivity relative to APTES. Additionally, the thin film structure may have a desired thickness by controlling the thickness of the first and second thin films 14 and 18. This thin film structure may be advantageously used for a gate insulation layer of a transistor or a dielectric layer of a capacitor.

Methods of Forming a Gate Structure

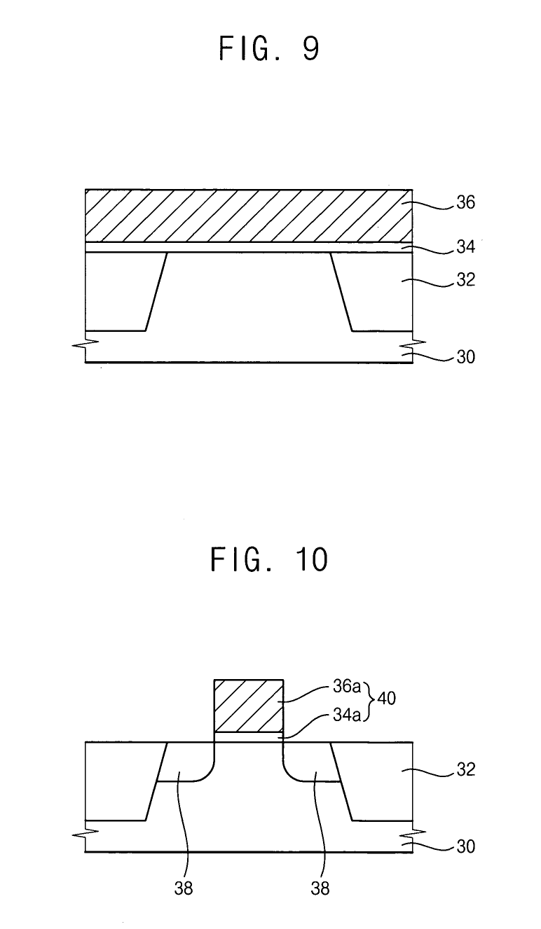

FIGS. 9 and 10 are cross-sectional views illustrating methods of forming a gate structure in accordance with some embodiments of the present invention.

Referring to FIG. 9, an isolation layer 32 is formed on a semiconductor substrate 30 to define an active region and a field region. The semiconductor substrate 30 may include, for example, a silicon wafer. The isolation layer 32 may be formed on the substrate 30 by an isolation process such as a shallow trench isolation (STI) process, although any suitable process may be used.

A gate insulation layer 34 is formed on the substrate 30 by the same or substantially the same as the processes described with reference to FIGS. 1 to 8. That is, the gate insulation layer 34 may include, for example, a first thin film of hafnium oxide and a second thin film of silicon oxide. Thus, the gate insulation layer 34 may include hafnium silicon oxide. When the gate insulation layer 34 is formed using an ALD process, the thicknesses of the first and the second thin films are advantageously controlled to thereby form the gate insulation layer 34 having a desired thickness on the substrate 30.

In some embodiments of the present invention, an additional oxide layer may be formed on the gate insulation layer 34. The additional oxide layer may include, for example, silicon oxide and have a thickness of about 5 Å. The additional oxide layer may be formed in-situ.

A gate conductive layer 36 is formed on the gate insulation layer 34. The gate conductive layer 36 may be formed using a conductive material, such as polysilicon doped with impurities or metal. Alternatively, the gate conductive layer 36 may include, for example, conductive metal nitride. The gate conductive layer 36 may be formed on the gate insulation layer 34 by a chemical vapor deposition (CVD) process or a sputtering process.

Referring to FIG. 10, the gate conductive layer 36 and the gate insulation layer 34 are partially etched to form a gate structure 40 on the active region of the substrate 30. The gate structure 40 includes, for example, a gate insulation layer pattern 34a and a gate conductive layer pattern 36a. The gate structure 40 may be formed on the substrate 30 by a photolithography process.

Source/drain regions 38 are formed at portions of the substrate 30 adjacent to the gate structure 40. The source/drain regions 38 may be formed by an ion implantation process.

In some embodiments of the present invention, a gate spacer may be formed on a sidewall of the gate structure 40 before forming the source/drain regions 38. When the gate spacer is formed on the sidewall of the gate structure 40, the source/drain regions 38 may be formed using the gate structure 40 and the gate spacer as implantation masks.

The gate insulation layer pattern 34a includes, for example, hafnium silicon oxide using TEMAH and APTES having a good reactivity relative to TEMAH. Therefore, the gate insulation layer pattern 34a has a thin equivalent oxide thickness (EOT) and a relatively high dielectric constant. When the gate structure 40 includes the gate insulation layer pattern 34a, a leakage current generated from the gate conductive layer pattern 36a may be effectively reduced or prevented.

Methods of Forming a Capacitor

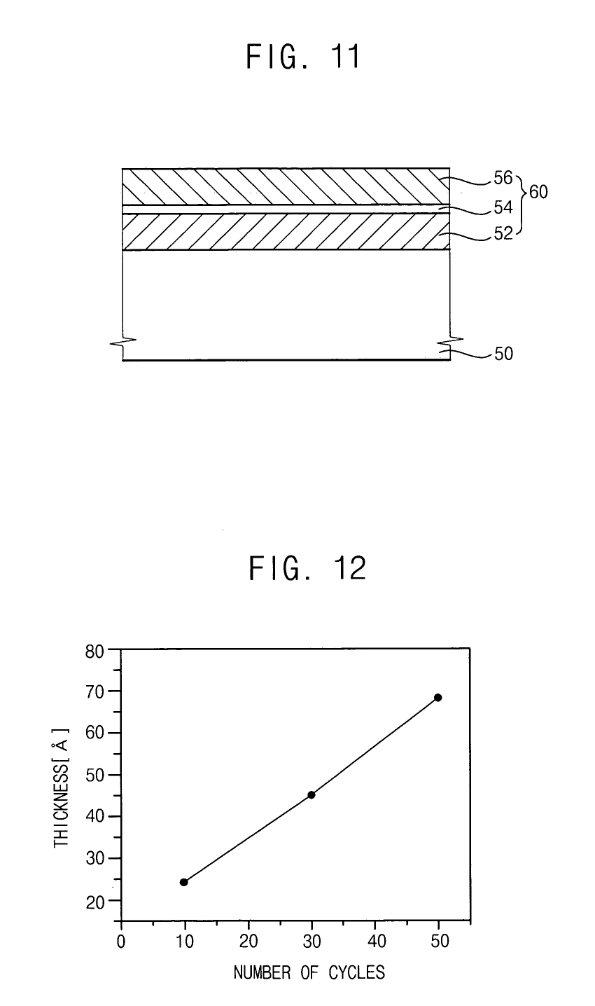

FIG. 11 is a cross-sectional view illustrating methods of forming a capacitor in accordance with some embodiments of the present invention. Referring to FIG. 11, a lower electrode 52 is formed on a substrate 50. The substrate 50 may include, for example, a silicon wafer. An underlying structure may be formed between the lower electrode 52 and the substrate 50. The underlying structure may include, for example, a gate structure, a conductive pattern, a pad, a contact, a bit line, etc.

The lower electrode 52 may be formed using a conductive material, such as doped polysilicon, metal, conductive metal nitride, etc. The lower electrode 52 may be formed on the substrate 50 or the underlying structure by a CVD process or a sputtering process. The lower electrode 52 may have a cylindrical shape to improve an effective area thereof.

A dielectric structure 54 is formed on the lower electrode 52 by the same or substantially the same processes as the processes described with reference to FIGS. 1 to 8. The dielectric structure 54 may have a first thin film of hafnium oxide and a second thin film of silicon oxide so that the dielectric structure 54 may include hafnium silicon oxide. When the dielectric structure 54 is formed by an ALD process, the thicknesses of the first and the second thin films are advantageously controlled, thereby forming the dielectric structure 54 having a desired thickness on the lower electrode 52.

An upper electrode 56 is formed on the dielectric structure 54. The upper electrode 56 may include, for example, the same or substantially the same material as that of the lower electrode 52. For example, the upper electrode 56 may include doped polysilicon, metal, conductive metal nitride, etc. The upper electrode 56 may be formed on the dielectric structure 54 by a CVD process or a sputtering process. As a result, a capacitor 60 including the lower electrode 52, the dielectric structure 54 and the upper electrode 56 is formed on the substrate 50.

The dielectric structure 54 of the capacitor 60 may be formed using TEMAH and APTES both of which have good reactivity with respect to each other. Thus, the capacitor 60 may have an improved capacitance and a relatively thin thickness because the dielectric structure 54 has a thin EOT and a relatively high dielectric constant.

Measurement of a Thickness Variation of a Thin Film Structure

FIG. 12 is a graph illustrating a thickness variation of a thin film structure including hafnium silicon oxide relative to cycles of manufacturing processes in accordance with some embodiments of the present invention.

In FIG. 12, the thin film structure, including hafnium silicon oxide, was formed by the same or substantially the same processes as those described with reference to FIGS. 1 to 8. The thin film structure was formed at a temperature of about 300° C. In a cycle of processes for forming the thin film structure, introducing a first reactant including TEMAH, introducing a first purge gas of argon, providing a first oxidant of ozone, introducing a second purge gas of argon, providing a second reactant including APTES, introducing a third purge gas of argon, providing a second oxidant of ozone, and introducing a fourth purge gas of argon were sequentially carried out. In particular, introducing the first reactant was performed for about 1 second, and introducing the first purge gas was carried out for about 1 second. Additionally, providing the first oxidant was executed for about 3 seconds, and introducing the second purge gas was performed for about 3 seconds. Providing the second reactant was performed for about 1 second, and introducing the third purge gas was executed for about 1 second. Furthermore, providing the second oxidant was carried out for about 3 seconds, and introducing the fourth purge gas was performed for about 3 seconds. When the thin film structure was formed on a substrate, an interface oxide film was formed between the thin film structure and the substrate. The interface oxide film had a thickness of about 12.3 Å.

As shown in FIG. 12, the thin film structure of hafnium silicon oxide had a thickness of about 1.12 Å after one cycle of the manufacturing processes. Here, an entire thickness of the thin film structure and the interface oxide film was about 13.42 Å. After ten cycles of the manufacturing process, the thin film structure including hafnium silicon oxide had a thickness of about 11.2 Å. Similarly, an entire thickness of the thin film structure and the interface oxide film was about 23.5 Å. After about thirty cycles of the manufacturing processes, the thin film structure, including hafnium silicon oxide, had a thickness of about 33.6 Å. An entire thickness of the thin film structure and the interface oxide film was about 45.9 Å. The thin film structure has a thickness of about 56.0 Å after about fifty cycles of the manufacturing process. An entire thickness of the thin film structure and the interface oxide film was about 68.3 Å.

When the thickness of the thin film structure is X and the number of the cycles is Y, a linear equation was obtained as follows:
Y=1.12X+12.3

Referring to FIG. 12 and the above equation, the thickness of the thin film structure was substantially in proportion to the number of the cycles of the manufacturing processes when the thin film structure, including hafnium silicon oxide, was formed using an ALD process.

Measurement of Impurities in a Thin Film Structure

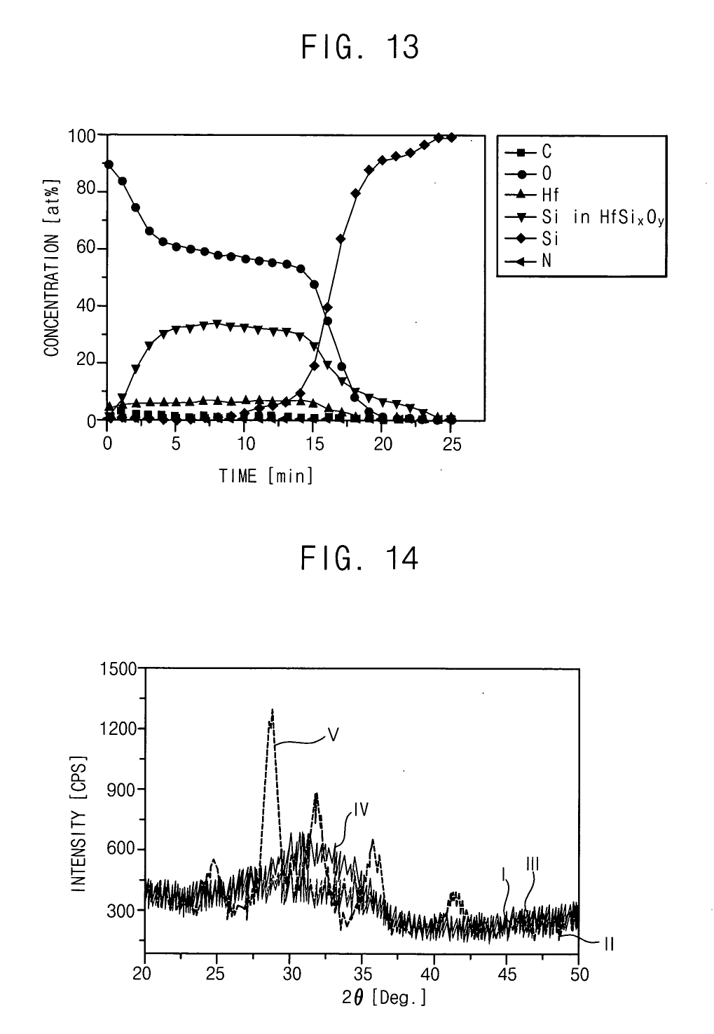

FIG. 13 is a graph illustrating impurity concentrations contained in a thin film structure including hafnium silicon oxide in accordance with some embodiments of the present invention.

In FIG. 13, the thin film structure was formed at a temperature of about 300° C. In a cycle of processes for forming the thin film structure, introducing a first reactant including TEMAH, introducing a first purge gas of argon, providing a first oxidant of ozone, introducing a second purge gas of argon, providing a second reactant including APTES, introducing a third purge gas of argon, providing a second oxidant of ozone, and introducing a fourth purge gas of argon were sequentially carried out. In particular, introducing the first reactant was performed for about 1 second, and introducing the first purge gas was carried out for about 1 second. Additionally, providing the first oxidant was executed for about 3 seconds, and introducing the second purge gas was performed for about 3 seconds. Providing the second reactant was performed for about 1 second, and introducing the third purge gas was executed for about 1 second. Furthermore, providing the second oxidant was carried out for about 3 seconds, and introducing the fourth purge gas was performed for about 3 seconds. The impurity concentrations were measured using an auger electron spectroscopy (AES) while sputtering the thin film structure of hafnium silicon oxide for about 25 minutes.

As shown in FIG. 13, silicon is early emitted from the thin film structure of hafnium silicon oxide. Thus, the thin film structure of hafnium silicon oxide sufficiently includes silicon therein because TEMAH has a good reactivity relative to APTES.

Evaluation of a Crystalline Structure of a Thin Film Structure

FIG. 14 is a graph showing crystalline structures of conventional thin films of hafnium oxide and thin film structures including hafnium silicon oxide in accordance with some embodiments of the present invention.

In FIG. 14, a first sample I, a second sample II and a third sample III were manufactured using processes the same or substantially the same as the processes described with reference to FIGS. 1 to 8.

The first sample I was prepared by repeatedly performing the following operations: introducing a first reactant including TEMAH, introducing a first purge gas of argon, providing a first oxidant of ozone, introducing a second purge gas of argon, providing a second reactant including APTES, introducing a third purge gas of argon, providing a second oxidant of ozone, and introducing a fourth purge gas of argon. Particularly, introducing the first reactant was performed for about 1 second, and introducing the first purge gas was carried out for about 1 second. Providing the first oxidant was executed for about 3 seconds, and introducing the second purge gas was performed for about 3 seconds. Providing the second reactant was performed for about 1 second, and introducing the third purge gas was executed for about 1 second. Providing the second oxidant was carried out for about 3 seconds, and introducing the fourth purge gas was performed for about 3 seconds. The first sample I was manufactured at a temperature of about 300° C. to have a thickness of about 109 Å. The second sample II was prepared by thermally treating the first sample I at a temperature of about 850° C. for about 30 seconds under a nitrogen atmosphere. The third sample III was manufactured by thermally treating the first sample I at a temperature of about 950° C. for about 30 seconds under a nitrogen atmosphere.

Meanwhile, a fourth sample IV and a fifth sample V were manufactured by a conventional method. Particularly, the fourth sample IV was manufactured by repeatedly performing a conventional ALD process using TDEAH as a hafnium precursor to have a thickness of about 95 Å. The fifth sample V was prepared by thermally treating the fourth sample IV at a temperature of about 850° C. for about 30 seconds under a nitrogen atmosphere.

Referring to FIG. 14, crystalline structures of the first to the fifth samples I to V were identified using an X-ray diffractometer. The first through third samples I to III had no crystalline structures, respectively. In particular, the second and third samples II and III were not crystallized even though the second and the third samples II and III were prepared by the above-described thermal treatments. However, the fourth and the fifth samples IV and V were crystallized at a temperature of about 300° C. Therefore, the thin film structure, including hafnium silicon oxide formed using TEMAH and APTES, has an amorphous crystalline structure without any crystallization at a high temperature.

Measurement of a Thickness Difference among Thin Film structures

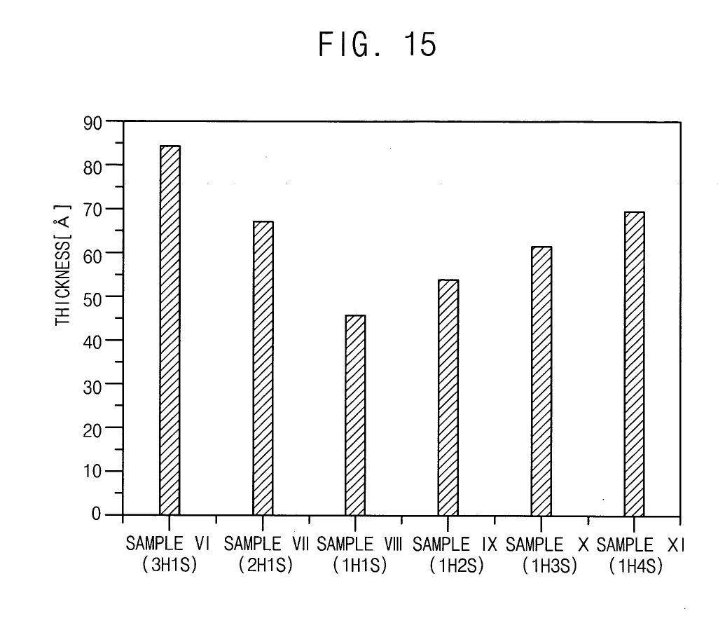

FIG. 15 is a graph illustrating thickness of thin film structures including hafnium silicon oxide in accordance with some embodiments of the present invention. In FIG. 15, “H” indicates a first cycle of processes that includes introducing TEMAH for about 1 second, introducing an argon gas for about 1 second, providing ozone for about 3 seconds, and introducing an argon gas for about 3 seconds at a temperature of about 300° C. Additionally, “S” indicates a second cycle of processes that includes introducing APTES for about 1 second, introducing an argon gas for about 1 second, providing ozone for about 3 seconds and introducing an argon gas for about 3 seconds at a temperature of about 300° C. When the first cycle H was performed once, a first thin film of hafnium oxide had a thickness of about 0.75 Å. After performing the second cycle S once, a second thin film of silicon oxide had a thickness of about 0.26 Å. When a thin film structure including the first and the second thin films was formed on a substrate, an interface oxide film having a thickness of about 15 Å was formed between the substrate and the thin film structure.

A sixth sample VI was prepared by performing an ALD process thirty times that includes executing the first cycle (3H) three times and carrying out the second cycle (1S) once. An entire thickness of the sixth sample VI and the interface oxide film was about 88.1 Å.

A seventh sample VII was manufactured by performing an ALD process thirty times that includes executing the first cycle (2H) twice and carrying out the second cycle (1S) once. An entire thickness of the seventh sample VII and the interface oxide film was about 67.2 Å.

An eighth sample VII was manufactured by performing an ALD process thirty times that includes executing the first cycle (1H) once and carrying out the second cycle (1S) once. An entire thickness of the eighth sample VII and the interface oxide film was about 47.3 Å.

A ninth sample IX was prepared by performing an ALD process thirty times that includes executing the first cycle (1H) once and carrying out the second cycle (2S) twice. An entire thickness of the ninth sample IX and the interface oxide film was about 52.6 Å.

A tenth sample X was manufactured by performing an ALD process thirty times that includes executing the first cycle (1H) once and carrying out the second cycle (3S) three times. An entire thickness of the tenth sample X and the interface oxide film was about 60.9 Å.

An eleventh sample XI was prepared by performing an ALD process thirty times that includes executing the first cycle (1H) once and carrying out the second cycle (4S) four times. An entire thickness of the eleventh sample XI and the interface oxide film was about 68.3 Å.

In forming the thin film structure that includes hafnium silicon oxide, the thickness of the thin film structure was varied in accordance with the numbers of the first cycle (H) for forming the first thin film and the second cycle (S) for forming the second thin film. Hence, the thin film structure may have a desired thickness by adjusting the numbers of the first cycle (H) and the second cycle (S). In addition, a concentration ratio between hafnium and silicon may be controlled by adjusting the numbers of the first cycle (H) and the second cycle (S).

Concentrations of hafnium and silicon in the sixth to the ninth samples VI to IX were measured using an X-ray photoelectron spectroscopy (XPS), thereby identifying the concentration ratios between hafnium and silicon contained in the thin film structures.

Table 1 shows the concentrations of hafnium and silicon and the concentration ratios between hafnium and silicon.

TABLE 1

| | | | | | Silicon/ |
|---|---|---|---|---|---|
| | Hafnium | Silicon | Carbon | Oxygen | (hafnium + |
| | (%) | (%) | (%) | (%) | silicon) (%) |
| Sample VI | 19.5 | 8.7 | 9.4 | 62.4 | 31 |
| Sample VII | 16.4 | 10.1 | 11.1 | 62.4 | 38 |
| Sample VIII | 12.9 | 14.0 | 9.0 | 64.2 | 52 |
| Sample IX | 8.9 | 17.8 | 7.6 | 65.8 | 66 |

As shown in Table 1, the concentration ratio between hafnium and silicon may be easily controlled by adjusting the concentrations of hafnium and silicon included in the sixth to the ninth samples VI to IX. Here, the concentrations of hafnium and silicon are controlled in accordance with the number of the first cycles (H) and the second cycles (S). Therefore, the thin film structure may include a desired concentration ratio between hafnium and silicon.

Although exemplary embodiments of the present invention have been discussed with regard to specific temperature and/or layer thickness ranges, it will be understood that any suitable temperature and/or layer thickness may be used.

According to the present invention, a thin film structure including hafnium silicon oxide may be easily formed using TEMAH and APTES both of which have good reactivity with respect to each other. Particularly, the thin film structure may have a desired concentration ratio between hafnium and silicon by controlling the numbers of the cycles of the manufacturing processes in the formation of the thin film structure using an ALD process.

Because the thin film structure has a relatively high dielectric constant, a semiconductor device including a transistor or a capacitor may have improved electrical characteristics when the thin film structure is used for a gate insulation layer of the transistor or a dielectric layer of the capacitor.

In concluding the detailed description, it should be noted that many variations and modifications can be made to the embodiments without substantially departing from the principles of the present invention. All such variations and modifications are intended to be included herein within the scope of the present invention, as set forth in the following claims.

That which is claimed:

1. A method of forming a thin film structure, comprising:
introducing a first reactant comprising tetrakis ethyl methyl amino hafnium (TEMAH) onto a substrate;
chemisorbing a first portion of the first reactant to the substrate, and physorbing a second portion of the first reactant to the first portion of the first reactant;
providing a first oxidant onto the substrate;
forming a first thin film comprising hafnium oxide on the substrate by chemically reacting the first oxidant with the first portion of the first reactant;
introducing a second reactant comprising amino propyl tri ethoxy silane (APTES) onto the first thin film;
chemisorbing a first portion of the second reactant to the first thin film, and physorbing a second portion of the second reactant to the first portion of the second reactant;
providing a second oxidant onto the first thin film; and
forming a second thin film comprising silicon oxide on the first thin film by chemically reacting the second oxidant with the first portion of the second reactant.

2. The method of claim 1, wherein the first oxidant comprises at least one selected from the group consisting of ozone (O₃), water (H₂O) vapor, hydrogen peroxide (H₂O₂), methanol (CH₃OH), and ethanol (C₂H₅OH).

3. The method of claim 1, wherein the second oxidant comprises at least one selected from the group consisting of ozone, water vapor, hydrogen peroxide, methanol, and ethanol.

4. The method of claim 1, wherein the thin film structure substantially comprises a gate insulation layer of a transistor.

5. The method of claim 1, wherein the thin film structure comprises a dielectric layer of a capacitor.

6. The method of claim 1, wherein introducing the first reactant, chemisorbing the first portion of the first reactant, physorbing the second portion of the first reactant, providing the first oxidant, forming the first thin film, introducing the second reactant, chemisorbing the first portion of the second reactant, physorbing the second portion of the second reactant, providing the second oxidant, and forming the second thin film are performed at temperature of about 150 to about 400° C.

7. The method of claim 1, wherein introducing the first reactant, chemisorbing the first portion of the first reactant, physorbing the second portion of the first reactant, providing the first oxidant and forming the first thin film are performed at least once.

8. The method of claim 1, wherein introducing the second reactant, chemisorbing the first portion of the second reactant, physorbing the second portion of the second reactant, providing the second oxidant, and forming the second thin film are performed at least once.

9. The method of claim 1, wherein introducing the first reactant, chemisorbing the first portion of the first reactant, physorbing the second portion of the first reactant, providing the first oxidant, forming the first thin film, introducing the second reactant, chemisorbing the first portion of the second reactant, physorbing the second portion of the second reactant, providing the second oxidant, and forming the second thin film are performed at least once.

10. The method of claim 1, further comprising:
removing the second portion of the first reactant;
removing an unreacted portion of the first oxidant;
removing the second portion of the second reactant; and
removing an unreacted portion of the second oxidant.

11. A method of forming a gate structure, comprising:
forming a gate insulation layer comprising hafnium silicon oxide on a substrate by an atomic layer deposition process using tetrakis ethyl methyl amino hafnium (TEMAH), amino propyl tri ethoxy silane (APTES), and oxidants;
forming a gate conductive layer on the gate insulation layer; and
forming a gate pattern comprising a gate insulation layer pattern and a gate conductive layer pattern by partially etching the gate conductive layer and the gate insulation layer.

12. The method of claim 11, wherein forming the gate insulation layer comprises:
introducing a first reactant comprising the TEMAH onto the substrate;
chemisorbing a first portion of the first reactant to the substrate, and physorbing a second portion of the first reactant to the first portion of the first reactant;
removing the second portion of the first reactant;
providing a first oxidant onto the substrate;
forming a first thin film comprising hafnium oxide on the substrate by chemically reacting the first oxidant with the first portion of the first reactant;
removing an unreacted portion of the first oxidant;
introducing a second reactant comprising the APTES onto the first thin film;
chemisorbing a first portion of the second reactant to the first thin film, and physorbing a second portion of the second reactant to the first portion of the second reactant;
removing the second portion of the second reactant;
providing a second oxidant onto the first thin film;
forming a second thin film comprising silicon oxide on the first thin film by chemically reacting the second oxidant with the first portion of the second reactant; and
removing an unreacted portion of the second oxidant.

13. The method of claim 12, wherein the first oxidant comprises at least one selected from the group consisting of ozone, water vapor, hydrogen peroxide, methanol, and ethanol.

14. The method of claim 12, wherein the second oxidant comprises at least one selected from the group consisting of ozone, water vapor, hydrogen peroxide, methanol, and ethanol.

15. The method of claim 12, wherein introducing the first reactant, chemisorbing the first portion of the first reactant, physorbing the second portion of the first reactant, removing the second portion of the first reactant, providing the first oxidant, forming the first thin film, removing the unreacted portion of the first oxidant, introducing the second reactant, chemisorbing the first portion of the second reactant, physorbing the second portion of the second reactant, removing the second portion of the second reactant, providing the second oxidant, forming the second thin film, and removing the unreacted portion of the second oxidant are performed at temperature of about 150 to about 400° C.

16. The method of claim 12, wherein introducing the first reactant, chemisorbing the first portion of the first reactant, physorbing the second portion of the first reactant, removing the second portion of the first reactant, providing the first oxidant, forming the first thin film, and removing the unreacted portion of the first oxidant are performed at least once.

17. The method of claim 12, wherein introducing the second reactant, chemisorbing the first portion of the second reactant, physorbing the second portion of the second reactant, removing the second portion of the second reactant, providing the second oxidant, forming the second thin film, and removing the unreacted portion of the second oxidant are performed at least once.

18. A method of forming a capacitor comprising:
forming a lower electrode on a substrate;
forming a dielectric structure comprising hafnium silicon oxide on the lower electrode by an atomic layer deposition process using tetrakis ethyl methyl amino hafnium (TEMAH), amino propyl tri ethoxy silane (APTES), and oxidants; and
forming an upper electrode on the dielectric structure.

19. The method of claim 18, wherein forming the dielectric structure comprises:
introducing a first reactant comprising the TEMAH onto the substrate;
chemisorbing a first portion of the first reactant to the substrate, and physorbing a second portion of the first reactant to the first portion of the first reactant;
removing the second portion of the first reactant;
providing a first oxidant onto the substrate;
forming a first thin film comprising hafnium oxide on the substrate by chemically reacting the first oxidant with the first portion of the first reactant;
removing an unreacted portion of the first oxidant;
introducing a second reactant comprising the APTES onto the first thin film;
chemisorbing a first portion of the second reactant to the first thin film, and physorbing a second portion of the second reactant to the first portion of the second reactant;
removing the second portion of the second reactant;
providing a second oxidant onto the first thin film;
forming a second thin film comprising silicon oxide on the first thin film by chemically reacting the second oxidant with the first portion of the second reactant; and
removing an unreacted portion of the second oxidant.

20. The method of claim 19, wherein the first oxidant comprises at least one selected from the group consisting of ozone, water vapor, hydrogen peroxide, methanol, and ethanol.

21. The method of claim 19, wherein the second oxidant comprises at least one selected from the group consisting of ozone, water vapor, hydrogen peroxide, methanol, and ethanol.

22. The method of claim 19, wherein introducing the first reactant, chemisorbing the first portion of the first reactant, physorbing the second portion of the first reactant, removing the second portion of the first reactant, providing the first oxidant, forming the first thin film, removing the unreacted portion of the first oxidant, introducing the second reactant, chemisorbing the first portion of the second reactant, physorbing the second portion of the second reactant, removing the second portion of the second reactant, providing the second oxidant, forming the second thin film, and removing the unreacted portion of the second oxidant are performed at temperature of about 150 to about 400° C.

23. The method of claim 19, wherein introducing the first reactant, chemisorbing the first portion of the first reactant, physorbing the second portion of the first reactant, removing the second portion of the first reactant, providing the first oxidant, forming the first thin film, and removing the unreacted portion of the first oxidant are performed at least once.

24. The method of claim 19, wherein introducing the second reactant, chemisorbing the first portion of the second reactant, physorbing the second portion of the second reactant, removing the second portion of the second reactant, providing the second oxidant, forming the second thin film, and removing the unreacted portion of the second oxidant are performed at least once.
